(19) United States
(12) Patent Application Publication
(10) Pub. No.: US 2025/0054812 A1
(43) Pub. Date: Feb. 13, 2025

(54) SELECTIVE BOTTOM-UP METAL FILL/CAP ON JUNCTION SILICIDE BY SELECTIVE METAL REMOVAL

(71) Applicant: Applied Materials, Inc., Santa Clara, CA (US)

(72) Inventors: Qihao ZHU, Sunnyvale, CA (US); Shumao ZHANG, San Jose, CA (US); Weifeng YE, San Jose, CA (US); Yiyang WAN, Sunnyvale, CA (US); Gary HOW, Santa Clara, CA (US); Jianqiu GUO, San Jose, CA (US); Dong WANG, Zhuhai (CN); Shihchung CHEN, Cupertino, CA (US); Liqi WU, San Jose, CA (US); Jiang LU, Milpitas, CA (US)

(21) Appl. No.: 18/400,819

(22) Filed: Dec. 29, 2023

Related U.S. Application Data
(60) Provisional application No. 63/532,022, filed on Aug. 10, 2023.

(51) Int. Cl. H01L 21/768; H01L 23/532; H01L 23/535

(52) U.S. Cl. CPC H01L 21/76889; H01L 21/76879; H01L 21/76895; H01L 23/53266; H01L 23/535

(57) ABSTRACT

Embodiments include a method of forming a contact structure on a semiconductor substrate. The method including selectively depositing a metal silicide layer over a contact formed within a cavity of a substrate and a bottom surface of the cavity using a selective deposition process, including forming a residual layer on a surface of a dielectric layer forming sidewalls of the cavity, wherein a thickness of the metal silicide layer deposited over the contact is greater than a thickness of the residual layer, removing at least a portion of the residual layer formed on the dielectric layer using an etching process that comprises exposing the metal selectively deposited layer to a metal halide containing precursor, and selectively depositing a metal fill over the metal silicide layer remaining over the contact after removing the at least the portion of the residual layer using a selective metal fill process.

### CROSS-REFERENCE TO RELATED APPLICATIONS

This application claims the benefit of U.S. Provisional Application Ser. No. 63/532,022, filed on Aug. 10, 2023, which is herein incorporated by reference.

### BACKGROUND

### Field

Embodiments of the present invention generally relate to methods for forming low resistivity contacts within a semiconductor device.

### Description of the Related Art

Integrated circuits have evolved into complex devices that can include millions of transistors, capacitors, and resistors on a single chip. In the course of integrated circuit evolution, functional density (i.e., the number of interconnected devices per chip area) has generally increased while geometry size (i.e., the smallest component (or line) that can be created using a fabrication process) has decreased.

Microelectronic devices are fabricated on a semiconductor substrate as integrated circuits in which various conductive layers are interconnected with one another to permit electronic signals to propagate within the device. Examples of such devices include memory (e.g., DRAM (dynamic random access memory)) and logic devices, including both planar and three-dimensional structures. Three-dimensional structures include fin field-effect transistor (finFET) or metal-oxide-semiconductor field-effect transistor (MOSFET) devices.

An example of finFET or MOSFET devices includes a gate electrode on a gate dielectric layer on a surface of a semiconductor substrate. Source/drain regions are provided along opposite sides of the gate electrode. The source and drain regions are generally heavily doped regions of the semiconductor substrate. Usually a metal silicide layer, for example a titanium silicide layer, is required to form a reliable contact at the formed source and drain regions.

In a traditional middle-end-of-the-line (MEOL) contact junction formation process, a feature also referred to a cavity, a via, or a trench, is fabricated in the semiconductor substrate. MEOL contact junctions allow connections between front-end-of-the-line (FEOL) semiconductor structures and back-end-of-the-line (BEOL) interconnects. Contacts with a low resistivity are desirable in semiconductor devices. However, when MEOL contacts have high resistance, the contacts produce poor connections between the FEOL structures and the BEOL packaging interconnects, reducing the performance of the packaged semiconductor structures.

In traditional MEOL contact formation, a plasma enhanced titanium tetrachloride (TiCl₄) process is used to form a titanium silicide (TiSi) layer on a silicon or silicon germanium connection as a capping layer. Because TiSi can be easily oxidized upon air exposure, the top of the TiSi layer is then nitridated to form titanium silicon nitride (TiSiN) to protect against the oxidation of the TiSi film. The final silicide capping layer is a bilayer of TiSi and TiSiN that is formed over the field, sidewalls and contact regions formed on the substrate.

Following the TiSi/TiSiN formation, the structure is filled with a low resistivity metal such as cobalt (Co) or tungsten (W). For example, a selective physical vapor deposition (PVD) W process may be used to fill the structure from the bottom-up. Then, TiSi (N)/W formed on the field and the sidewall are removed by a pull-back process, and only the PVD W remains at the bottom of the structure. However, due to PVD technology limitations, it is challenging to deposit a continuous PVD W film at the high sloped area of the capping layer which can include the surface of the formed contact and/or the junction between the formed contact and the feature's sidewall. Therefore, to ensure good W coverage especially in the sloped area, a low growth rate selective, fluorine free, atomic layer deposition (ALD) tungsten (W) process (FFW) is deposited on top of the PVD W. The ALD W layer provides not only a good barrier, but also a high quality seed layer for a following high rate selective chemical vapor deposition (CVD) W process. However, such an integration flow not only has high resistivity due to the TiSi/TiSiN bilayer, but also high cost due to the expensive thick FFW ALD deposition process and the pull-back process for thick TIN/PVD W.

There is a need for improved methods to reduce contact resistance and simplified processes of contact formation.

### SUMMARY

In an embodiment, a method of forming a contact structure on a semiconductor substrate includes selectively depositing a metal silicide layer over a contact formed within a cavity of a substrate and a bottom surface of the cavity using a selective deposition process, the selective deposition process forming a residual layer on a surface of a dielectric layer forming sidewalls of the cavity, wherein a thickness of the metal silicide layer deposited over the contact is greater than a thickness of the residual layer, removing at least a portion of the residual layer formed on the dielectric layer using an etching process, wherein the etching process comprises exposing the metal selectively deposited layer to a metal halide containing precursor, and selectively depositing a metal fill over the metal silicide layer remaining over the contact after removing the at least the portion of the residual layer formed on the dielectric layer using a selective metal fill process.

In another embodiment, a method of forming a contact structure on a semiconductor substrate includes selectively depositing a metal silicide layer over a contact formed within a cavity of a substrate and a bottom surface of the cavity using a selective deposition process, the selective deposition process forming a residual layer on a surface of a dielectric layer forming sidewalls of the cavity, wherein a thickness of the metal silicide layer deposited over the contact is greater than a thickness of the residual layer, removing at least a portion of the residual layer using a soaking process, the soaking process comprising exposing the metal silicide layer to an amount of a metal halide containing precursor and a for a period of time, and selectively depositing a metal fill over the metal silicide layer remaining over the contact after removing the at least the portion of the residual layer formed on the dielectric layer using a selective metal fill process.

In another embodiment, a processing system includes a plurality of processing chambers, a controller, a memory for storing instructions, which, when executed by the controller, causes the controller to perform a method in a first one of the processing chambers for forming a feature on a substrate, the method comprising selectively depositing a metal silicide layer over a contact formed within a cavity of a substrate and a bottom surface of the cavity using a selective deposition process, the selective deposition process forming a residual layer on a surface of a dielectric layer forming sidewalls of the cavity, wherein a thickness of the metal silicide layer deposited over the contact is greater than a thickness of the residual layer; removing at least a portion of the residual layer formed on the dielectric layer using an etching process, wherein the etching process comprises exposing the metal selectively deposited layer to a metal halide containing precursor and selectively depositing a metal fill over the metal silicide layer remaining over the contact after removing the at least the portion of the residual layer formed on the dielectric layer using a selective metal fill process.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 illustrates a method for reducing contact resistance in accordance with one or more embodiments.

FIGS. 2A-2E illustrate cross-sectional views of a portion of a semiconductor structure during the method for reducing contact resistance in accordance with one or more embodiments.

FIG. 3 illustrates an integrated tool in accordance with one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Methods of the present disclosure provide contacts that have a reduced resistivity. Methods can integrate multiple processes on the same integrated tool as well as achieve low contact resistance (Rc). For example, a metal removal step that integrates a conformal plasma-enhanced titanium (PE-Ti) deposition or selective chemical vapor deposition Ti (CVD-Ti) and an in-situ molybdenum (Mo) or tungsten (W) metal fill/capping eliminates a highly resistive metal silicide layer and reduces the high cost associated with the need to form a fluoride free tungsten (FFW) film at a desired thickness.

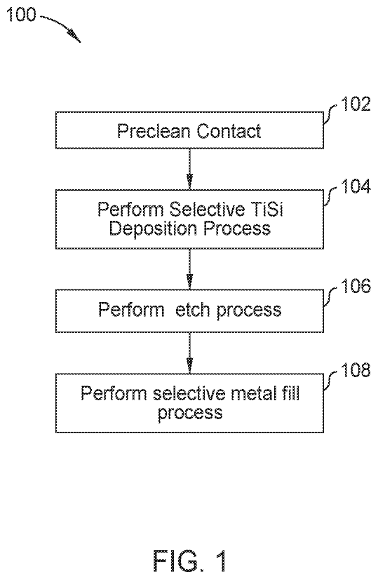

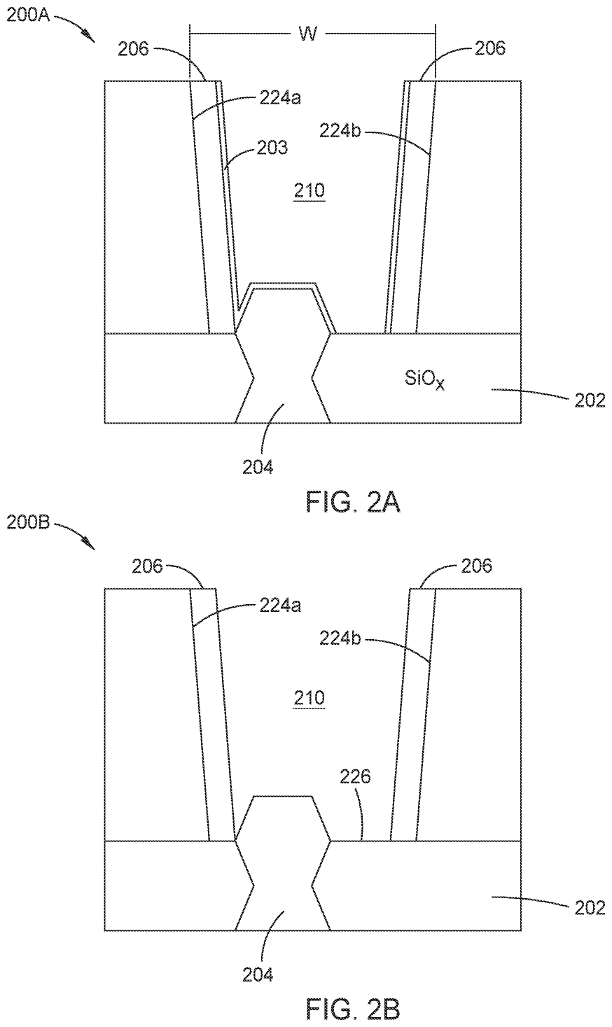

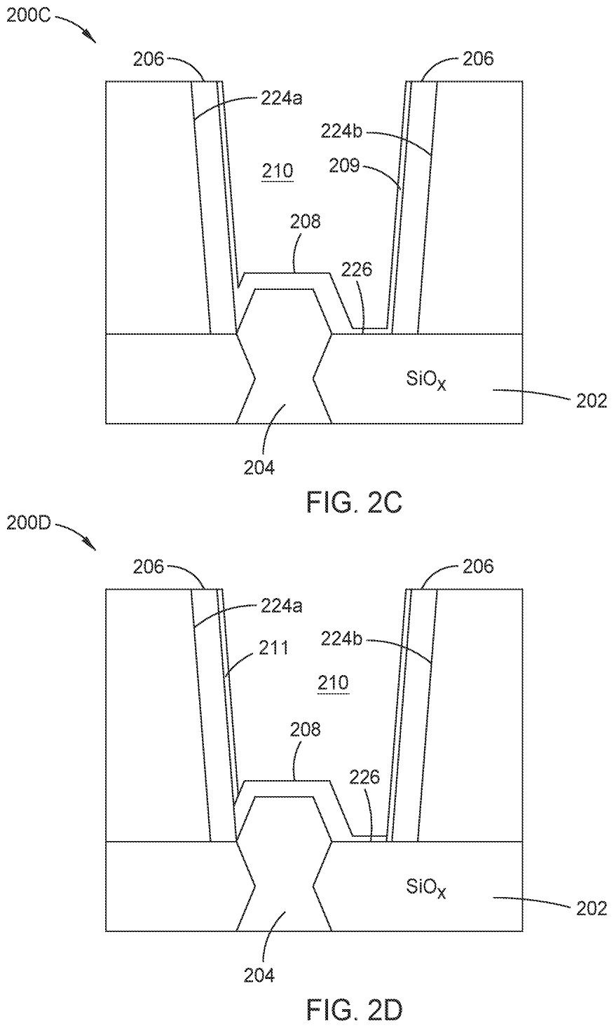

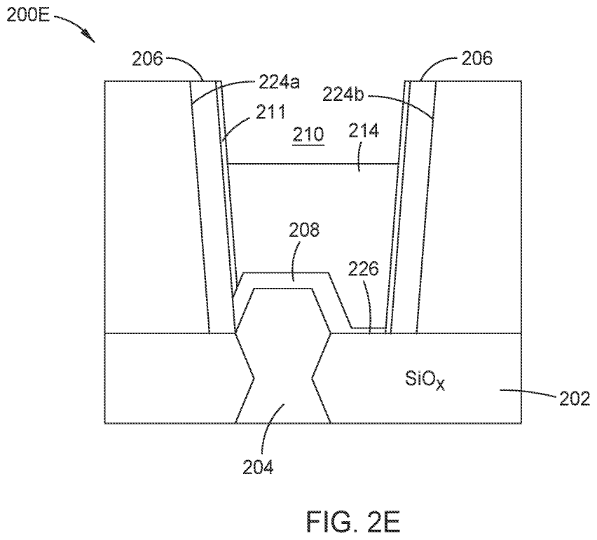

FIG. 1 illustrates a method 100 for reducing contact resistance, in accordance with one or more embodiments. FIGS. 2A-2E illustrate cross-sectional views of a portion of a semiconductor structure during the method 100 for reducing contact resistance. In the discussion of the method 100, references will be made to the views 200A-200E of FIGS. 2A-2E.

At block 102, a preclean process is performed to remove any contaminates and/or oxidation from surfaces of a contact structure as depicted in a view 200A of FIG. 2A. The contact structure has a silicon-based portion 204 (i.e., a contact) that is exposed in a cavity 210 of a substrate 202 formed of a dielectric material (e.g., silicon dioxide, silicon nitride, etc.). In some examples, the silicon-based portion 204 is formed through a bottom surface 226 of the cavity 210. In some embodiments, the silicon-based portion 204 may be a silicon material or a silicon germanium (SiGe) material. In one or more examples, a dielectric layer 206 comprising a different material than the substrate 202 may be formed on sidewalls 224a and 224b of the cavity 210. In another example, the dielectric layer is not formed on sidewalls 224a and 224b of the cavity 210 and thus the cavity 210 is formed within a dielectric layer 206 that is disposed across the surface of the substrate 202. In some embodiments, the dielectric layer 206 includes a low-k dielectric, silicon oxide, or other useful dielectric material. In one example, dielectric layer 206 contains a low-k dielectric material, such as a silicon carbide oxide material or a carbon doped silicon oxide material, for example, BLACK DIAMOND® II low-k dielectric material, available from Applied Materials, Inc., located in Santa Clara, California.

In one or more embodiments, cavities (e.g., vias), such as cavity 210 can have an average width W. For example, cavity 210 can have a width W (FIG. 2A) of about 35 nanometers (nm) or less, such as about 5 nm to about 35 nm, such as about 5 nm, 10 nm, and 15 nm to about 20 nm, 25 nm, 30 nm, or 35 nm. In one or more embodiments, cavity 210 can have an aspect ratio (depth:width) of about 1:1 to about 100:1, such as about 5:1, 10:1.

For example, as shown in the view 200B of FIG. 2B, the preclean process is performed to remove a native oxide material 203 (FIG. 2A) formed on sidewalls 224a and 224b of the cavity 210 and on the surface of the silicon-based portion 204. In one or more examples, the preclean process may include exposing the substrate 202 to the reducing agent during a thermal process or a plasma process. Reducing agents that are useful during the pre-treatment process include hydrogen (e.g., H₂ or atomic-H), ammonia (NH₃), a hydrogen and ammonia mixture (H₂/NH₃), atomic-N, hydrazine (N₂H₄), alcohols (e.g., methanol, ethanol, or propanol), derivatives thereof, plasmas thereof, or combinations thereof. Substrate 200 may be exposed to a plasma formed in-situ or remotely during the preclean process. In some embodiments of block 102, substrate 200 is exposed to a plasma preclean process to remove contaminants from the surfaces of the cavity 210. Substrate 202 may be positioned within a processing chamber, exposed to a reducing agent, and heated to a temperature within a range from about 100° C. to about 400° C., such as about 200° C. or about 250° C. In some embodiments, substrate 202 may be exposed to the plasma (e.g., in situ or remotely) for a time period within a range from about 2 seconds to about 60 seconds. The plasma may be produced at a power within the range from about 200 watts to about 1,000 watts, such as 350 watts.

In block 104, a selective deposition process is performed to produce a metal silicide layer 208 on the silicon-based portion 204 as depicted in view 200C of FIG. 2C. In one or more examples, the metal silicide layer 208 may comprise, titanium silicide (TiₓSi_{y}) which may include Ti₅Si₃, TiSi₂, TiSi, or combinations thereof. The process is selective to the silicon-based portion 204 over the dielectric material of the substrate 202, but a thin residual layer 209 may also form on the dielectric layer 206 and the bottom surface 226 of the cavity 210. The residual layer 209 may comprise Ti, TiSi, TIN, TiClₓ or the like. In one or more examples, the metal silicide layer 208 is deposited using a low selective direct plasma-enhance titanium (PE-TI) process. In other examples, the metal silicide layer 208 is deposited using a CVD TiSi process. In examples in which the dielectric layer 206 is not formed on sidewalls 224a, 224b, the residual layer 209 may be formed directly onto the sidewalls 224a and 224b.

In block 106, an etch process is performed to remove the residual layer 209 from the dielectric layer 206 formed on sidewalls 224a, 224b. In one example, the etch process is a soaking process. The soaking process may comprise soaking the substrate 202 in a processing chamber using a gas precursor. In one example the gas precursor may include molybdenum (Mo), tungsten (W), or a metal halide containing precursor used to partially or fully remove the residual layer 209 formed on sidewalls 224a, 224b. In some embodiments, the gas precursor essentially comprises a metal halide containing precursor such as tungsten pentachloride (WCl₅), tungsten hexachloride (WCl₆), or molybdenum pentachloride (MoCl₅). In some examples, the soaking process also removes a portion of the metal silicide layer 208. In one example, due to the aspect ratio of the cavity, the soaking process removes a smaller portion (i.e., less) of the metal silicide layer 208 than the residual layer 209. In another example the soaking process removes equal amounts of the metal silicide layer 208 and the residual layer 209. After the soaking process, the thickness of the metal silicide layer 208 is greater than the thickness of the residual layer 209. Thus at the competition of block 106 there is still a remaining thickness of the metal silicide layer on the bottom surface 226. In one or more examples, the soaking process may include a molybdenum halide soak using a molybdenum halide precursor such as molybdenum pentachloride (MoCl₅). In another example, the soaking process may be a tungsten halide soak using a tungsten halide precursor such as tungsten pentachloride (WCl₅) or tungsten hexachloride (WCl₆). Stated differently, the soaking process may include exposing the residual layer 209 to an amount of the gas precursor, such as a metal halide containing precursor for a period of time. The soaking process may be performed at a chamber pressure of between about 5 Torr and about 50 Torr. The soaking process may include flowing the precursor (i.e., a Mo or W precursor as described above) in the presence of a carrier gas, such as argon (or another noble gas), at flow rate between about 100 sccm and about 2000 sccm, for example, 1000 sccm for a period of time between 1s and 100s seconds, such as 10s. The soaking process may be performed at a process chamber temperature of between about 250° C. and about 500° C., for example, 400° C.

In one or more examples, as shown in the view 200D of FIG. 2D, the soaking process may partially remove the residual layer 209 formed on sidewalls 224a, 224b and/or at the very least form a passive metal residue layer 211 by passivating the remaining portion of the residual layer 209 formed on sidewalls 224a, 224b. It is believed that, due to the preferred selective deposition of the metal silicide layer 208 on the silicon-based portion 204 during block 104, the thickness of the residual layer 209 will be significantly thinner than the metal silicide layer 208 formed over the silicon-based portion 204. Therefore, during the completion of the soaking process performed during block 106 the residual layer 209 will be completely, or nearly completely (e.g., residual islands of the metal silicide layer 208), removed and only a small but equal portion of the metal silicide layer 208 formed over the silicon-based portion 204 will be removed.

In block 108, and as shown in the view 200E of FIG. 2E, a selective metal fill process may be used to deposit a metal fill 214 over the metal silicide layer 208. The metal fill 214 may comprise depositing Mo or W within the cavity 210. In one or more examples, the selective metal fill process is a bottom-up metal fill process used to selectively deposit a metal fill 214 in the cavity 210 and over the remaining metal silicide layer 208. The selective metal fill process may include exposing the metal silicide layer 208 to a metal precursor, such as a Mo precursor or a fluorine-free-tungsten (FFW) precursor along with a suitable reducing agent, such as hydrogen (H₂). In one example, Mo precursor and the FFW precursor are chlorine (CI) containing precursors. In one example, the selective metal fill process is a CVD process using a Mo precursor and is used to fill the cavity 210 and a connected junction silicide to a metal network.

In another example, the selective metal fill process can be used to form a metal fill 214 that functions as a thin metal cap to cover all junction silicide using either a Mo precursor such as MoCl₅, or a fluorine-free-tungsten (FFW) precursor. In other examples, the selective metal fill process can be an ALD deposition process or a pulsed CVD bottom-up fill process (i.e., cycling a CVD process steps and purge steps). The selective metal fill process may be performed at a chamber pressure between about 10 Torr and about 300 Torr, for example. The selective metal fill process may include flowing the metal precursor at a flow rate in the presence of a reducing agent, such as hydrogen (H₂) or diborane (B₂H₆) and a carrier gas such as argon (or another noble gas). The flow rate of the reducing agent may be between about 1000 sccm and 20000 sccm. The carrier gas flow rate between about 100 sccm and about 2000 sccm, for example, 700 sccm. The selective metal fill process may be performed at a temperature of between about 250° C. and about 500° C., for example, 400° C. The etch process (block 106) and the selective metal fill process (block 108) may be performed in the same or different processing chambers.

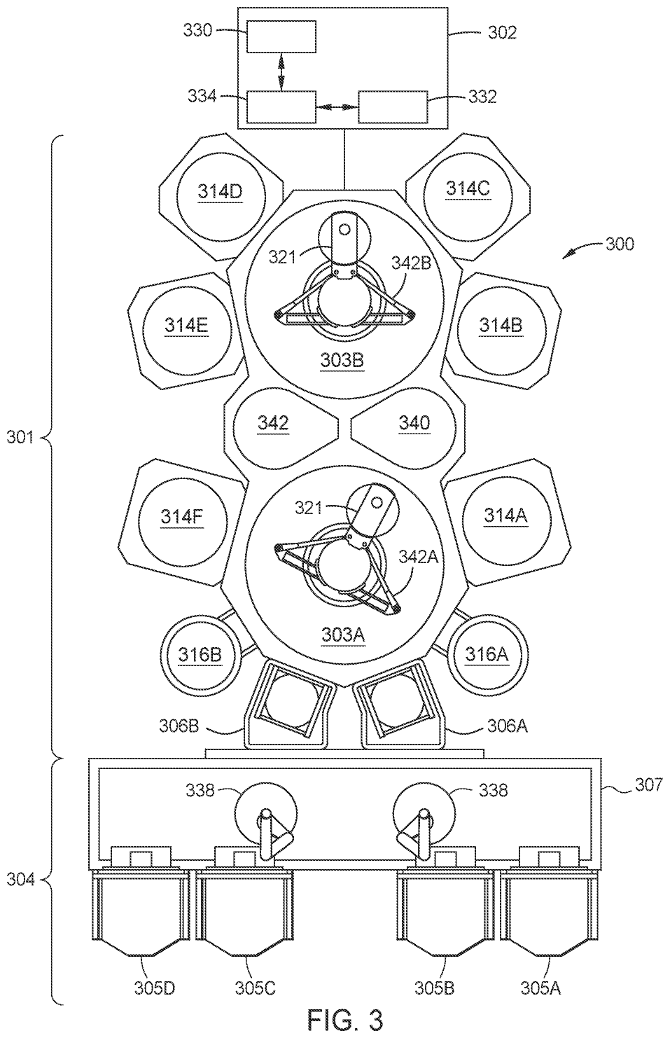

The methods of the present disclosure may be performed in individual process chambers that may be provided as part of a cluster tool, for example, the integrated tool 300 (e.g., cluster tool) described below with respect to FIG. 3. The advantage of using an integrated tool 300 is that there is no vacuum break between chambers and, therefore, no requirement to degas and pre-clean a substrate before treatment in a chamber. For example, in some embodiments the methods of the present disclosure may advantageously be performed in an integrated tool such that there are limited or no vacuum breaks between processes, limiting or preventing contamination of the substrate such as oxidation and the like. The integrated tool 300 includes a vacuum-tight processing platform 301, a factory interface 304, and a system controller 302. The processing platform 301 comprises multiple processing chambers, such as 314A, 313B, 314C, 314D, 314E, and 314F operatively coupled to a vacuum substrate transfer chamber (transfer chambers 303A, 303B). The factory interface 304 is operatively coupled to the transfer chamber 303A by one or more load lock chambers (two load lock chambers, such as 306A and 306B)

In some embodiments, the factory interface 304 comprises at least one docking station 307, at least one factory interface robot 338 to facilitate the transfer of the semiconductor substrates. The docking station 307 is configured to accept one or more front opening unified pod (FOUP). Four FOUPS, such as 305A, 305B, 305C, and 305D are shown in the embodiment of FIG. 3. The factory interface robot 338 is configured to transfer the substrates from the factory interface 304 to the processing platform 301 through the load lock chambers, such as 306A and 306B. Each of the load lock chambers 306A and 306B have a first port coupled to the factory interface 304 and a second port coupled to the transfer chamber 303A. The load lock chamber 306A and 306B are coupled to a pressure control system (not shown) which pumps down and vents the load lock chambers 306A and 306B to facilitate passing the substrates between the vacuum environment of the transfer chamber 303A and the substantially ambient (e.g., atmospheric) environment of the factory interface 304. The transfer chambers 303A, 303B have vacuum robots 342A, 342B disposed in the respective transfer chambers 303A, 303B. The vacuum robot 342A is capable of transferring substrates 321 between the load lock chamber 306A, 306B, the processing chambers 314A and 314F and a cooldown station 340 or a pre-clean station 342. The vacuum robot 342B is capable of transferring substrates 321 between the cooldown station 340 or pre-clean station 342 and the processing chambers 314B, 314C, 314D, and 314E.

In some embodiments, the processing chambers 314A, 314B, 314C, 314D, 314E, and 314F are coupled to the transfer chambers 303A, 303B. The processing chambers 314A, 314B, 314C, 314D, 314E, and 314F may comprise, for example, preclean chambers, ALD process chambers, PVD process chambers, remote plasma chambers, CVD chambers, or the like. The chambers may include any chambers suitable to perform all or portions of the methods of the present disclosure, as discussed above. In some embodiments, one or more optional service chambers (shown as 316A and 316B) may be coupled to the transfer chamber 303A. The service chambers 316A and 316B may be configured to perform other substrate processes, such as degassing, orientation, substrate metrology, cool down, and the like.

The processing chambers 314A, 314B, 314C, 314D, 314E, and 314F may be any appropriate chamber for processing a substrate. In some examples, a processing chamber may be capable of performing an etch process, a cleaning process, an annealing process, a CVD deposition process, or an ALD deposition processes. As used herein, CVD refers to chemical vapor deposition and ALD refers to atomic line deposition. In some embodiments, a processing chamber is a Selectra™ Etch chamber available from Applied Materials of Santa Clara, Calif. In some embodiments, a processing chamber is a SiCoNi™ Pre-clean chamber available from Applied Materials of Santa Clara, Calif. In some embodiments, a processing chamber may be a Centura™ Epi chamber, Volta™ CVD/ALD chamber, or Encore™ PVD chamber, all available from Applied Materials of Santa Clara, Calif.

The system controller 302 controls the operation of the tool 300 using a direct control of the process chambers 314A, 314B, 314C, 314D, 314E, and 314F or alternatively, by controlling the computers (or controllers) associated with the process chambers 314A, 314B, 314C, 314D, 314E, and 314F and the tool 300. In operation, the system controller 302 enables data collection and feedback from the respective chambers and systems to optimize performance of the tool 300. The system controller 302 generally includes a Central Processing Unit (CPU) 330, a memory 334, and a support circuit 332. The CPU 330 may be any form of a general-purpose computer processor that can be used in an industrial setting. The support circuit 332 is conventionally coupled to the CPU 330 and may comprise a cache, clock circuits, input/output subsystems, power supplies, and the like. Software routines, such as a method as described above may be stored in the memory 334 and, when executed by the CPU 330, transform the CPU 330 into a specific purpose computer (system controller) 302. The software routines may also be stored and/or executed by a second controller (not shown) that is located remotely from the tool 300.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

Certain embodiments and features have been described using a set of numerical upper limits and a set of numerical lower limits. It should be appreciated that ranges including the combination of any two values, e.g., the combination of any lower value with any upper value, the combination of any two lower values, and/or the combination of any two upper values are contemplated unless otherwise indicated. Certain lower limits, upper limits and ranges appear in one or more claims below. All numerical values are “about” or “approximately” the indicated value, and taken into account experimental error and variations that would be expected by a person having ordinary skill in the art.

Likewise whenever a composition, an element or a group of elements is preceded with the transitional phrase “comprising”, it is understood that we also contemplate the same composition or group of elements may be modified with other transitional phrases, such as “consisting essentially of,” “consisting of”, “selected from the group of consisting of,” or “is” preceding the recitation of the composition, element, or elements and vice versa. The phrases, unless otherwise specified, “consists essentially of” and “consisting essentially of” do not exclude the presence of other steps, elements, or materials, whether or not, specifically mentioned in this specification, so long as such steps, elements, or materials, do not affect the basic and novel characteristics of the claimed features, additionally, the phrases do not exclude impurities and variances normally associated with the elements and materials used.

While the foregoing is directed to embodiments of the present principles, other and further embodiments of the principles may be devised without departing from the basic scope thereof.

What is claimed is:

1. A method of forming a contact structure on a semiconductor substrate, comprising:
selectively depositing a metal silicide layer over a contact formed within a cavity of a substrate and a bottom surface of the cavity using a selective deposition process, the selective deposition process forming a residual layer on a surface of a dielectric layer forming sidewalls of the cavity, wherein a thickness of the metal silicide layer deposited over the contact is greater than a thickness of the residual layer;
removing at least a portion of the residual layer formed on the dielectric layer using an etching process, wherein the etching process comprises exposing the metal selectively deposited layer to a metal halide containing precursor; and
selectively depositing a metal fill over the metal silicide layer remaining over the contact after removing the at least the portion of the residual layer formed on the dielectric layer using a selective metal fill process.

2. The method of claim 1, wherein the metal halide containing precursor essentially comprises tungsten pentachloride (WCl₅), tungsten hexachloride (WCl₆), or molybdenum pentachloride (MoCl₅).

3. The method of claim 1, wherein the metal silicide layer comprises titanium silicide (TiₓSi_{y}).

4. The method of claim 1, wherein the etching process comprises a soaking process that comprises exposing at least the residual layer to an amount of the metal halide containing precursor for a first period of time.

5. The method of claim 4, wherein the soaking process comprises exposing the substrate to an amount of a tungsten (W) precursor or molybdenum (Mo) precursor.

6. The method of claim 5, wherein the Mo precursor is molybdenum pentachloride (MoCl₅).

7. The method of claim 1, wherein selectively depositing a metal fill over the metal silicide layer comprises exposing the metal silicide layer to a metal halide containing precursor and a reducing agent.

8. The method of claim 1, wherein the metal fill layer comprises tungsten (W) or molybdenum (Mo).

9. The method of claim 1, wherein the selective metal fill process is an atomic layer deposition (ALD) process, a pulsed chemical vapor deposition (CVD) process, or a CVD process.

10. The method of claim 1, wherein the selective etching process removes a portion of the residual layer and passivates a remaining portion of the residual layer.

11. The method of claim 1, wherein the selective etching process removes the entire residual layer.

12. A method of forming a contact structure on a semiconductor substrate, comprising:
selectively depositing a metal silicide layer over a contact formed within a cavity of a substrate and a bottom surface of the cavity using a selective deposition process, the selective deposition process forming a residual layer on a surface of a dielectric layer forming sidewalls of the cavity, wherein a thickness of the metal silicide layer deposited over the contact is greater than a thickness of the residual layer;
removing at least a portion of the residual layer using a soaking process, the soaking process comprising exposing the metal silicide layer to an amount of a metal halide containing precursor for a period of time; and
selectively depositing a metal fill over the metal silicide layer remaining over the contact after removing the at least the portion of the residual layer formed on the dielectric layer using a selective metal fill process.

13. The method of claim 12, wherein the metal halide containing precursor essentially comprises tungsten pentachloride (WCl₅), tungsten hexachloride (WCl₆), or molybdenum pentachloride (MoCl₅).

14. The method of claim 12, wherein the metal silicide layer comprises titanium silicide (TiₓSi_{y}).

15. The method of claim 12, wherein selectively depositing a metal fill over the metal silicide layer comprises exposing the metal silicide layer to a metal halide containing precursor and a reducing agent

16. A processing system comprising:
a plurality of processing chambers;
a controller;
a memory for storing instructions, which, when executed by the controller, causes the controller to perform a method in a first one of the processing chambers for forming a feature on a substrate, the method comprising:
selectively depositing a metal silicide layer over a contact formed within a cavity of a substrate and a bottom surface of the cavity using a selective deposition process, the selective deposition process forming a residual layer on a surface of a dielectric layer forming sidewalls of the cavity, wherein a thickness of the metal silicide layer deposited over the contact is greater than a thickness of the residual layer;
removing at least a portion of the residual layer formed on the dielectric layer using an etching process, wherein the etching process comprises exposing the metal selectively deposited layer to a metal halide containing precursor; and
selectively depositing a metal fill over the metal silicide layer remaining over the contact after removing the at least the portion of the residual layer formed on the dielectric layer using a selective metal fill process.

17. The processing system of claim 16, wherein the metal halide containing precursor essentially comprises tungsten pentachloride (WCl₅), tungsten hexachloride (WCl₆), or molybdenum pentachloride (MoCl₅)

18. The processing system of claim 16, wherein the instructions for the etching process further comprise instructions perform a soaking process comprising exposing at least the residual layer to an amount of the metal halide containing precursor for a first period of time.

19. The processing system of claim 16, wherein the metal silicide layer comprises titanium silicide (TiₓSi_{y}).

20. The processing system of claim 19, wherein the instructions for selectively depositing the metal fill over the metal silicide layer comprise instructions to exposing the metal silicide layer to a metal halide containing precursor and a reducing agent.
